(19) United States
(12) Patent Application Publication
(10) Pub. No.: US 2007/0281447 A1
(43) Pub. Date: Dec. 6, 2007

(54) Method of loading and/or unloading wafer in semiconductor manufacturing apparatus

(76) Inventors: Hyung-Goo Lee, Suwon-si (KR); Ki-Tae Ki, Sinan-gun (KR); Eui-Hwan Kim, Guri-si (KR); Young-Il Shin, Seoul (KR); Kwang-Han Lee, Seoul (KR); Chang-Sik Jun, Yongin-si (KR); Kyoung-Hwan Chin, Suwon-si (KR); Byung-Chul Choi, Hwaseong-si (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/637,789

(22) Filed: Dec. 13, 2006

(30) Foreign Application Priority Data
May 30, 2006 (KR) 2006-48878

(51) Int. Cl. H01L 21/20; C23C 16/00

(52) U.S. Cl. 438/478; 118/729

(57) ABSTRACT

In a method of unloading and/or loading a wafer in a semiconductor device manufacturing apparatus, pumping and/or purge operations are performed in a process chamber while the wafer is separated from a susceptor by a desired distance using a plurality of lift pins.

### BACKGROUND OF THE INVENTION

1. Field of the Invention

Embodiments of the present invention relate generally to a method of manufacturing a semiconductor device. More particularly, embodiments of the invention relate to a method of loading and unloading a wafer in a semiconductor processing apparatus.

A claim of priority is made to Korean Patent Application 10-2006-0048878, filed on May 30, 2006, the disclosure of which is hereby incorporated by reference in its entirety.

2. Description of Related Art

Semiconductor devices are generally manufactured by performing a large number of processing steps on a wafer. For instance, most semiconductor devices are manufactured through steps such as impurity ion implantation processes, thin film deposition processes, etching and planarization processes, cleaning processes, and so on. The impurity ion implantation processes are typically used is to implant impurity ions such as group 3B ions (e.g., Boron), or group 5B ions (e.g., Phosphorus or Arsenic), into a semiconductor substrate. Thin film deposition processes are used to form an insulation or conductive material film on a semiconductor substrate. The etching processes are used to form patterns in the insulation or conductive material film. The planarization processes are used to polish or remove parts of various layers such as interlayer insulation layers formed on the semiconductor substrate. Finally, the cleaning are used to remove contaminants from the semiconductor substrate or from a processing chamber.

The above processes may be performed multiple times under various different conditions. In addition, many of these processes may be performed in different respective process chambers. Accordingly, it is often necessary to move a wafer from one process chamber and another between processes.

To position a wafer for processing in a particular process chamber, the wafer is generally loaded onto a susceptor or chuck within the process chamber. The susceptor typically includes a lift device for lifting the wafer up and down, a guide ring for increasing processing efficiency and guide pins to prevent the wafer from sliding.

FIG. 1 is a plan view illustrating a susceptor for a conventional chemical vapor deposition (CVD) device. FIG. 2 is a sectional view of the susceptor taken along a line A-A′ in FIG. 1.

Referring to FIGS. 1 and 2, a wafer W to undergo a CVD process is loaded onto susceptor 10. A plurality of guide pins 14 are installed in susceptor 10, to prevent the loaded wafer W from sliding. Guide pins 14 are inserted into respective pin holes 12 formed with a predetermined depth in susceptor 10. The configuration of guide pins 14 prevents wafer W from sliding when it is loaded or unloaded in susceptor 10.

Although susceptor 10 may prevent wafer W from sliding, susceptor 10 may also be faced with a number of problems. For example, as illustrated in FIG. 3, when wafer W is loaded on susceptor 10, it may rest on a particular one of guide pins 14, or alternatively, it may collide with one of guide pins 14. Further, where the particular guide pin 14 is not securely fixed in a corresponding pin hole 12, the particular guide pin 14 may be removed from the pin hole 12, potentially damaging wafer W or interfering with the processing of wafer W.

Another problem with susceptor 10 is that particles such as by-products of processes may invade the interior of pin holes 12, polluting the interior of the process chamber and potentially causing irregular process margins or arcing on wafer W.

FIG. 4 illustrates an one exemplary structure of one of guide pins 14 labeled with reference number B in FIG. 1. As shown in FIG. 4, where the guide pin 14 is inserted into pin hole 12, a process gas 16 for a CVD process is injected into the process chamber and process gas 16 also invades into the interior of pin hole 12. Guide pin 14 is not fixed into pin hole 12, and therefore it may be lifted up by process gas 16. If sufficiently lifted, guide pin 14 may be exit pin hole 12 and be dropped onto wafer W, causing defects and possibly loss of the entire wafer W.

As described above, in conventional device for performing a CVD process, guide pins 14 are installed in susceptor 10 in order to prevent wafer W from sliding. However, guide pins 14 may be pulled out of pin hole 12 or contamination may collect in pin hole 12, resulting in processing defects, irregular process margins, scratching of wafer W, and so on, which in turn may result in lost wafers.

### SUMMARY OF THE INVENTION

According to one embodiment of the invention, a method comprises introducing a semiconductor wafer into a process chamber in a semiconductor manufacturing apparatus, and mounting the wafer on an elevated lift pin in the process chamber. With the wafer mounted on the elevated lift pin, air is pumped from the process chamber. After the air is pumped from the process chamber, the lift pin is lowered to mount the wafer on a susceptor. With the wafer mounted on the susceptor a process is performed on the wafer. After the process is performed on the wafer, the lift pin is elevated to separate the wafer from the susceptor. With the wafer separated from the susceptor, a purge gas is injected into the process chamber. Finally, after the purge gas is injected into the process chamber, the wafer is removed from the process chamber.

According to another embodiment of the invention, a method of loading and unloading a wafer in a semiconductor manufacturing apparatus is provided. The method comprises introducing the wafer into a process chamber, and mounting the wafer on an elevated lift pin such that the wafer is separated from a susceptor by a distance “C”. With the wafer mounted on the elevated lift pin and separated from the susceptor by the distance “C”, a pumping operation is performed to control an internal pressure of the process chamber. The lift pin is then lowered to load the wafer onto the susceptor. With the wafer loaded on the susceptor, a process is performed on the wafer. After the process is performed on the wafer, the lift pin is elevated to separate the wafer from the susceptor by a distance “D”. With the wafer separated from the susceptor by the distance “D”, a purge gas is injected into the process chamber to create a constant pressure in the process chamber above and below the wafer. After the purge gas is injected into the process chamber, the wafer is removed from the process chamber.

According to still another embodiment of the invention, a method of unloading a wafer in a semiconductor device manufacturing apparatus is provided. The method comprises mounting the wafer on a susceptor within a process chamber and performing a process on the wafer. After performing the process is performed on the wafer, a lift pin is elevated to separate the wafer from the susceptor. With the wafer separated from the susceptor, a purge gas is injected into the process chamber. After the purge gas is injected into the process chamber, the wafer is removed from the process chamber.

### BRIEF DESCRIPTION OF THE DRAWINGS

Embodiments of the invention are described in relation to the accompanying drawings. Throughout the drawings like reference numbers indicate like exemplary elements, components, and steps. In the drawings:

FIG. 1 is a plan view illustrating a conventional CVD device;

FIG. 2 is a cross-sectional view taken along a line A-A in FIG. 1;

FIG. 3 illustrates a wafer resting on an upper part of a guide pin shown in FIG. 1;

FIG. 4 illustrates an enlarged structure of a guide pin shown in FIG. 1;

FIG. 5 is a diagram of a semiconductor processing apparatus adapted to employ a wafer loading and unloading method according to selected embodiments of the invention;

FIG. 6 is a flowchart for a plasma-enhanced tetraethylorthosilicate (PETEOS) film deposition process performed using a plasma reinforced CVD device and a wafer loading and unloading method according to selected embodiments of the invention; and

FIGS. 7A through 7C sequentially illustrate a lift pin drive procedure performed using the semiconductor device manufacturing device shown in FIG. 5.

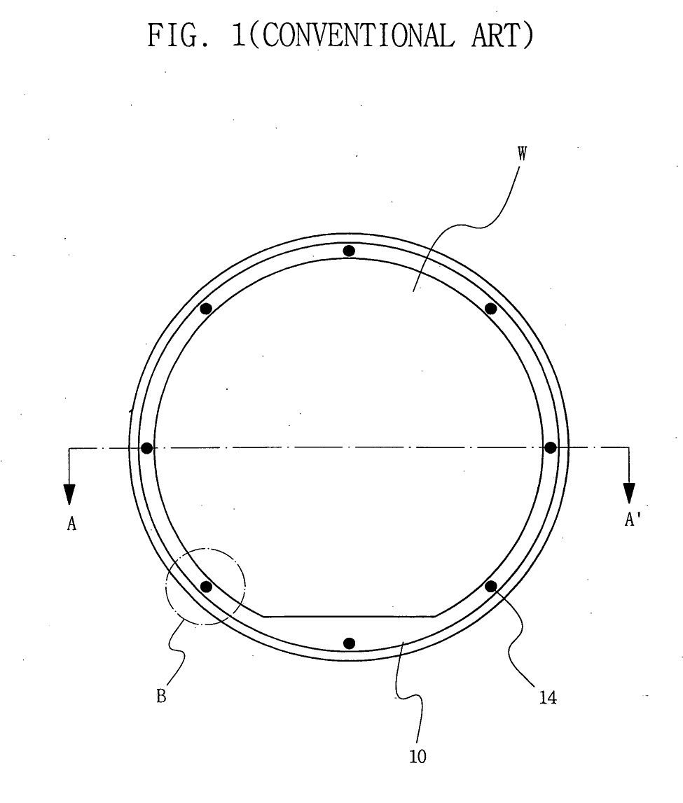

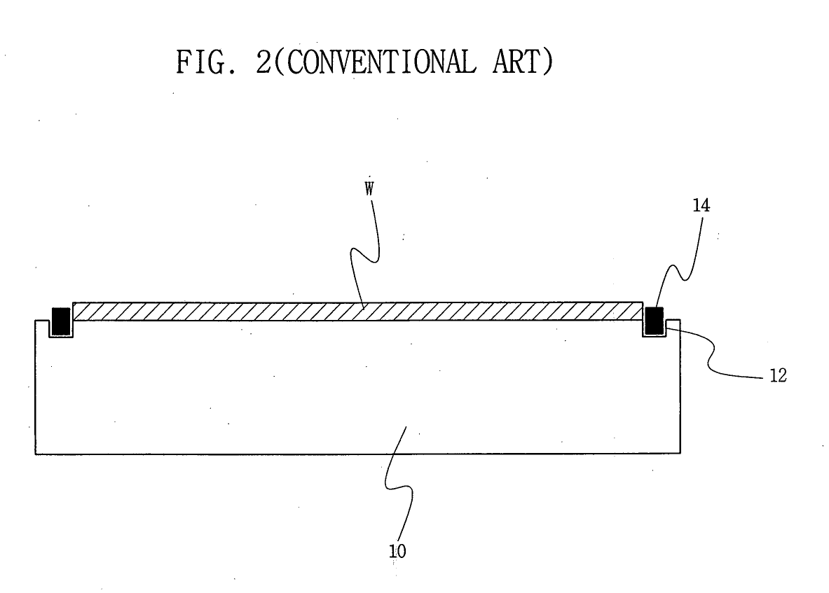

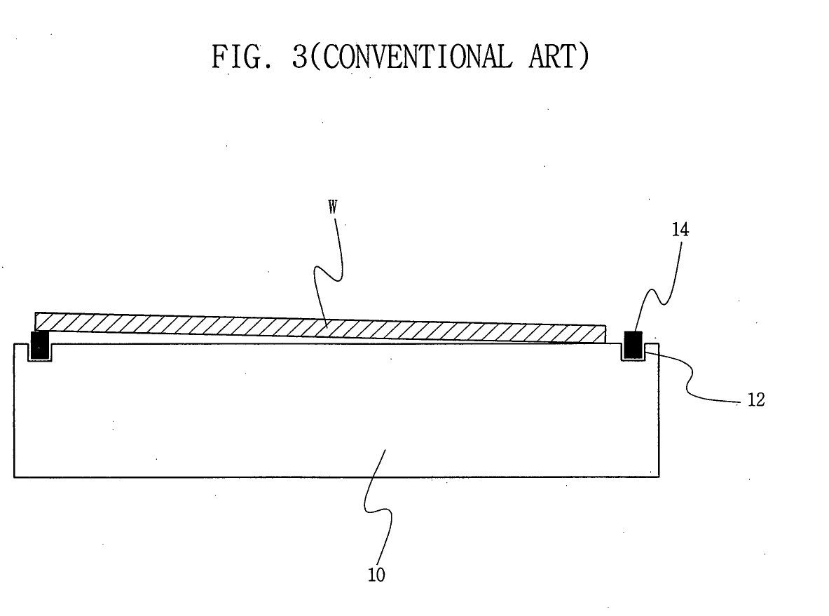

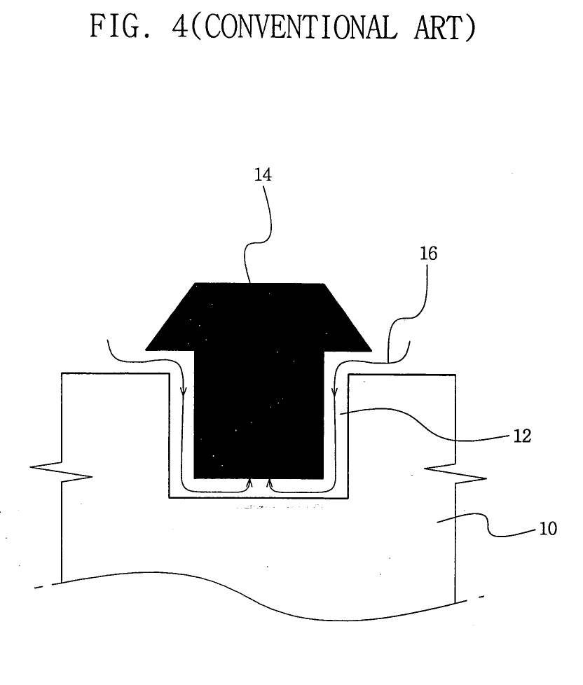

### DESCRIPTION OF EXEMPLARY EMBODIMENTS

Exemplary embodiments of the invention are described below with reference to the corresponding drawings. These embodiments are presented as teaching examples. The actual scope of the invention is defined by the claims.

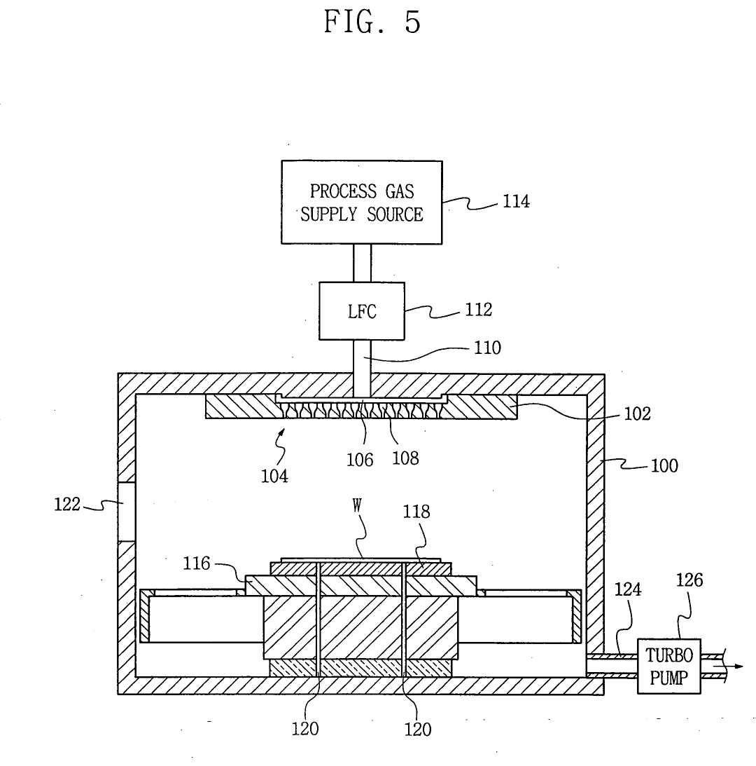

FIG. 5 illustrates a semiconductor manufacturing apparatus adapted to perform a wafer loading and unloading method according to selected embodiments of the invention. FIG. 5 also illustrates a plasma reinforced CVD device used in a PETEOS film deposition process.

Referring to FIG. 5, the apparatus comprises a process chamber 100 providing a controlled environment for wafer processing. A top electrode 102 is formed in an upper part of the process chamber 100. Top electrode 102 is adapted to receive a first radio frequency (RF) power signal. The first RF power signal typically has a power of about 350 watts and is used to generate plasma in the interior of process chamber 100.

A shower head 104 is also formed in the upper part of process chamber 100. Shower head 104 is typically formed of quartz or a ceramic material that is stronger and has better insulation characteristics than quartz. Shower head 104 includes a buffer space 106 for temporarily storing process gas(es) supplied through a process gas injection hole 110, and a plurality of gas spray holes 108 for spraying the process gas stored in buffer space 106 into the interior of process chamber 100.

Shower head 104 is coupled to process gas injection hole 110 and process gas(es) for a PETEOS film deposition process are injected into process gas injection hole 110 from a process gas supply source. The process gases flowing from process gas supply source 114 preferably comprise O₂ and tetra-ethyl-ortho-silicate (TEOS). The amount of the gases is typically controlled by a liquid flow controller (LFC) 112. Process gas injection hole 110 may include a heater for heating the process gases to a desired temperature.

A bottom electrode 116 is formed in a lower region of process chamber 100. A second RF power signal is applied to bottom electrode 116. A susceptor 118 adapted to support a wafer W is formed on bottom electrode 116. The second RF power signal is typically applied to bottom electrode 116 with a low frequency of about 700 watt or less, and functions as an electric power source for a plasma formation, together with the first RF power signal applied to top electrode 102. A slit door valve 122 is formed in a side part of process chamber 100 as a wafer injection hole. Wafer W is loaded into process chamber 100 and onto susceptor 118 through slit door valve 122 for a PETEOS process.

Susceptor 118 is equipped with lift pins 120 used to lift wafer W up and down. Lift pins 120 are raised and lowered under the control of a drive unit, and wafer W provided through slit door valve 122 may be loaded or unloaded from susceptor 118 through raising or lowering lift pins 120.

Although not shown in the drawings, a clamp ring may be installed at an edge portion of susceptor 118. The clamp ring is typically formed in a circular shape large enough to encompass an edge portion of wafer W mounted on susceptor 118, and enables an overall region of the wafer to undergo a plasma reaction by enlarging a plasma environmental region to an outer side portion of wafer W. The clamp ring is typically formed of material, such as silicon carbide (SiC), having high strength, abrasion resistance, acid-resistance, heat-resistance, and impact resistance.

An exhaust line 124 is formed on an outer side of process chamber 100. Exhaust line 124 is typically connected to a vacuum device such as a turbo pump 126 in order to discharge particles such as residual process gas and process by-products from process chamber 100 and/or to maintain a desired pressure inside process chamber 100.

A PETEOS film deposition process is performed with a controlled environment inside process chamber 100. Turbo pump 126 is used to maintain the interior of process chamber 100 in a pressure state adequate for the PETEOS film deposition process. In other words, to deposit a PETEOS film on wafer W, wafer W is inserted into process chamber 100 through slit door valve 122. Where slit door valve 122 is opened, an atmospheric pressure of a transfer chamber (not shown) may affect the pressure state of process chamber 100. For example, an interior pressure of process chamber 100 may increase to about 1×10⁻³ torr.

However, to counteract the effects of the transfer chamber on the interior pressure of process chamber 100 during the process of introducing wafer W into process chamber 100, turbo pump 126 may be driven to pump air out of process chamber 100. By pumping air out of process chamber 100, the interior pressure of process chamber 100 may be maintained at about 1×10⁻⁶ torr, as required for the PETEOS film deposition process.

Turbo pump 126 may additionally be coupled to a dry pump (not shown). The dry pump is an auxiliary pumping device similar to turbo pump 126 and used to pump air out of process chamber 100. In addition, an oil system (not shown) and a water flow (not shown) may be used to regulate the effects of heat produced by the dry pump.

In general, turbo pump 126 is only used to maintain the pressure of process chamber 100, while the dry pump can be used to maintain the pressure of process chamber 100 and the transfer chamber. More particularly, the dry pump may serve a buffering function to maintain a particular vacuum state. Where slit door valve 122 is opened to insert wafer W into process chamber 100 or where process gas for the PETEOS film deposition process is injected into process chamber 100, the internal pressure of process chamber 100 temporarily increases. However, turbo pump 126 may be driven to maintain a desired interior pressure in process chamber 100 during the PETEOS film deposition process. This driving of turbo pump 126 during the PETEOS film deposition process further serves to remove non-reactive gas(es) and reactive by-products generated during the PETEOS film deposition process from process chamber 100.

In conventional semiconductor processing apparatuses, a wafer may slide around on a susceptor due to a pressure difference between upper and lower faces of the wafer during wafer loading and unloading procedures. The conventional apparatuses attempt to address the wafer sliding problem by providing guide pins with the susceptor. However, as described above, the guide pins can cause problems such as contamination or damage to the wafer.

Accordingly, in selected embodiments of the invention, the guide pins used in the conventional apparatuses are omitted. To compensate for the absence of the guide pins, the loading and unloading procedures can be modified so that lift pins 120 raise and lower wafer W onto susceptor 118.

Once wafer W is inserted into process chamber 100 through slit door 122 and mounted on lift pins 120, a turbo pumping operation is performed to control the pressure in process chamber 100. More particularly, where wafer W is mounted on an upper part of lift pins 120, a gap having a predetermined height is formed between susceptor 118 and wafer W. Where the turbo pumping operation is performed with the gap between susceptor 118 and wafer W, a pressure above and below wafer W is maintained at a similar or substantially equal level, preventing wafer W from sliding.

After the turbo pumping operation is completed, lift pins 120 are lowered to mount wafer W on susceptor 118. Then, a PETEOS film deposition process is performed. After the PETEOS film deposition process is performed, lift pins 120 are elevated to separate wafer W from susceptor 118. Next, a purge operation is performed. Where the purge for the process chamber is performed with wafer W separated from susceptor 118, the same or similar pressure atmosphere is maintained above and below wafer W, preventing wafer W from sliding. Various methods of loading and unloading a wafer from a semiconductor manufacturing apparatus are described in further detail below with reference to FIGS. 5 through 7.

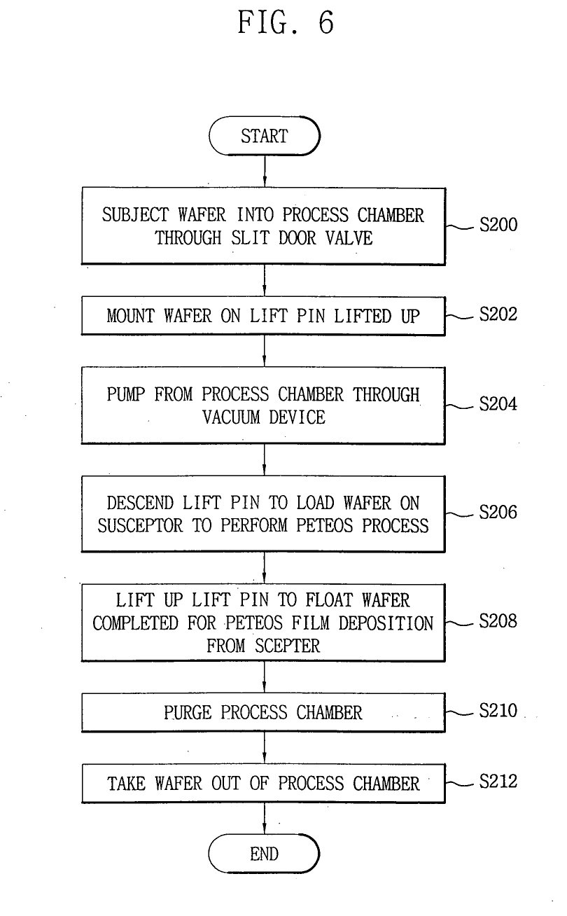

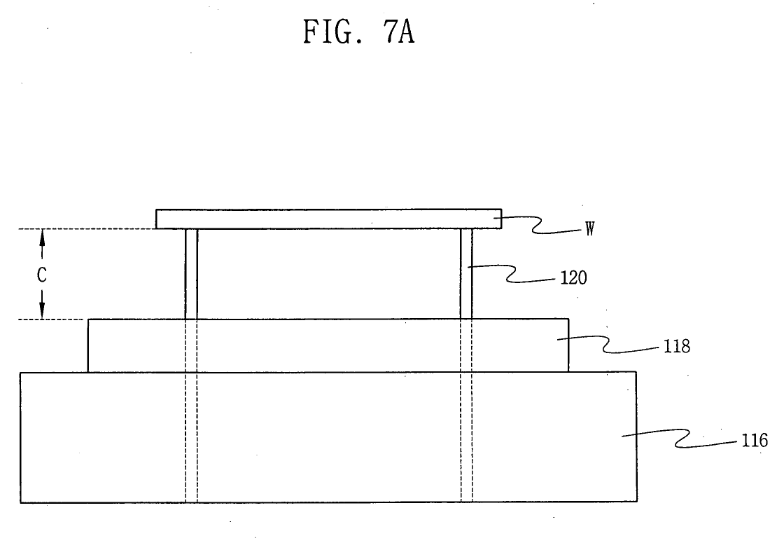

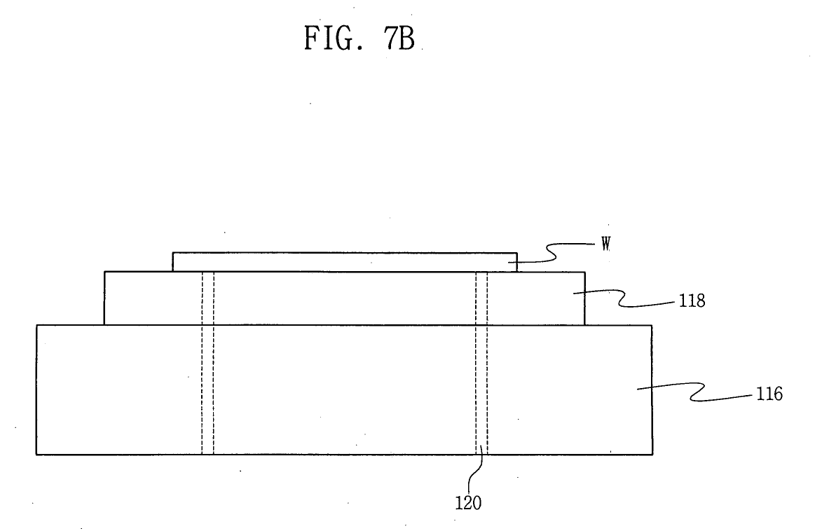

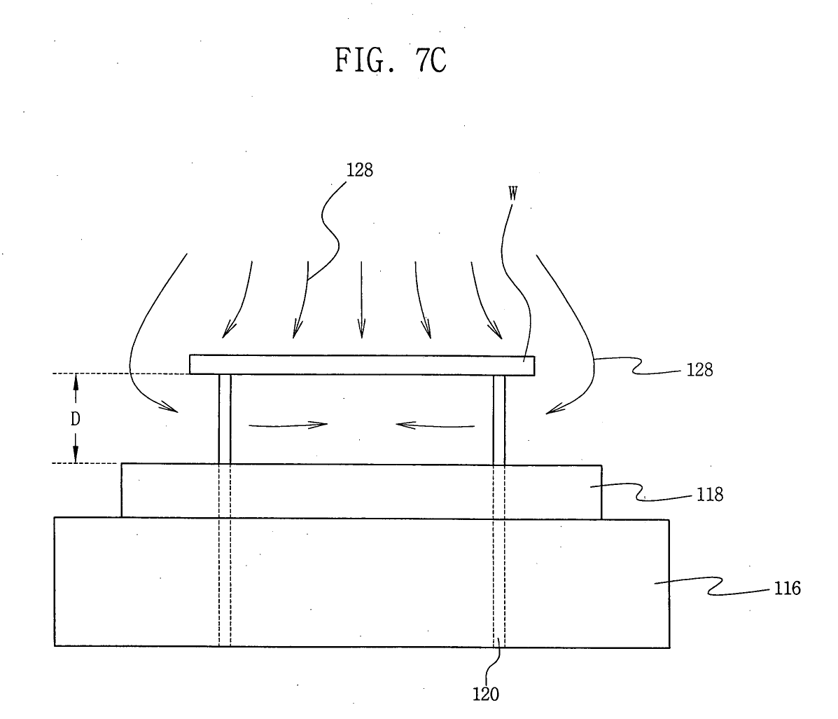

FIG. 6 is a flowchart for a PETEOS film deposition process performed by a plasma reinforced CVD device and an associated wafer loading and unloading method according to selected embodiments of the invention. FIGS. 7A through 7C sequentially illustrate a driving procedure for lift pins 120 in the plasma reinforced CVD device shown in FIG. 5.

FIG. 7A illustrates steps S200 and S202 for loading wafer W onto lift pins 120. More particularly, as illustrated in FIGS. 6 and 7A, in step S200, wafer W is introduced into process chamber 100 through slit door valve 122. When wafer W is introduced into process chamber 100, lift pins 120 are raised to a desired height. Then, in step S202, wafer W is transferred by a robot arm onto an upper part of lift pins 120. Once wafer W is mounted on lift pins 120, slit door valve 122 is closed to shield process chamber 100 from the outside transfer chamber. Next, a vacuum atmosphere is formed in the interior of process chamber 100 through the operation of turbo pump 126.

When first mounted on lift pins 120, wafer W is separated from susceptor 118 by a distance “C”. At this time, air is pumped out of process chamber 100 using turbo pump 126 in a step S204. Generally, when slit door valve 122 is opened to insert wafer W into process chamber 100, air in the transfer chamber flows into process chamber 100 and the pressure of process chamber 100 may increase to a level of about 1×10⁻³ torr. Turbo pump 126 is then driven to lower the pressure of process chamber 100 to a level of about 1×10⁻⁶ torr, which is desirable for the PETEOS film deposition process.

To maintain a high vacuum state in process chamber 100, a gas blast within the interior of turbo pump 126 may rotate at a high speed over 27,000 rpm. However, when turbo pump 126 initially pumps, a strong rotary force of the gas blast may cause air flow in process chamber 100, which can cause wafer 126 to move if already resting on susceptor 118. In other words, if wafer W is loaded onto susceptor 118 when turbo pump 126 begins pumping, a relatively high vacuum atmosphere may be formed in an upper part of wafer W through the operation of turbo pump 126, while a relatively lower vacuum atmosphere may be formed in a lower part of wafer W. Accordingly, the pressure above wafer W may be lower than the pressure below wafer W. As a consequence of this pressure difference, wafer W may float and slide toward turbo pump 126. In other words, if the position of wafer W is not fixed by a physical device or mechanism, wafer W may slide and be dropped due to a strong suction force from turbo pump 126.

Accordingly, as illustrated by FIG. 7A, turbo pump 126 begins to be driven while wafer W is mounted on lift pins 120 at a height “C” above susceptor 118 so that substantially the same pressure is maintained on upper and lower surfaces of wafer W. By maintaining the upper and lower parts of wafer W at substantially the same pressure, wafer W is prevented from sliding around.

Subsequently, as illustrated by FIG. 7B, wafer W is lowered onto susceptor 118 for a PETEOS film deposition step. In the configuration of FIG. 7B, the interior pressure of process chamber 100 has been lowered to form a relatively high vacuum atmosphere for the PETEOS film deposition and lift pins 120 have been lowered to load wafer W onto susceptor 118. Next, in a step S206, a PETEOS film deposition process is performed. In the PETEOS film deposition process, process gas(es) for PETEOS film deposition are injected into process chamber 100 through process gas injection line 110. The process gas(es) may comprise, for example, O₂ supplied at a rate of about 1100 standard cubic centimeters per minute (SCCM) and TEOS supplied at a rate of about 0˜3 standard liters per minute (SLM).

During the PETEOS film deposition process, the interior pressure of process chamber 100 is preferably maintained at about 2.0 torr and the temperature of process chamber 100 is preferably maintained at about 300˜400° C. The first and second RF power signals are applied to top electrode 102 and bottom electrode 116, respectively, to generate oxygen plasma. To transform O₂ flowing into process chamber 100 into a plasma state, the first RF power signal is applied to top electrode 102 at a level of about 350 watts and the second RF power signal is applied to bottom electrode 116 at a level of about 700 watts.

In response to the first and second RF power signals, the O₂ is separated into O+ ions having a positive charge (+), electrons having a negative charge (−) and O* radicals as neutral particles not having charge, thus forming oxygen plasma in process chamber 100. The O* radicals and TEOS compound chemically react to form a PETEOS film on wafer W.

FIG. 7C illustrates a step of unloading wafer W from susceptor 118 and process chamber 100. After the PETEOS film is formed to a desired thickness on wafer W using the PETEOS film deposition process, lift pins 120 are elevated to lift wafer W to a distance “D” above susceptor 118 in a step S208.

Before wafer W is removed from process chamber 100, a purge step using a purge gas 128 such as argon is performed in a step S210 to remove residual process gas(es) and by-products such particles generated in process chamber 100 during the PETEOS film deposition process. Purge gas 128 spreads throughout process chamber 100 and is preferably uniformly diffused in the space between wafer W and susceptor 118 and above wafer W as illustrated by arrows in FIG. 7C.

In contrast to conventional systems where a purge gas is sprayed while a wafer rests on a susceptor, purge gas 128 is sprayed while wafer W is separated from susceptor 118 by distance D. In the conventional system, guide pins are used to prevent the wafer from moving. However, as illustrated by FIG. 7C, selected embodiments of the invention prevent sliding movements of wafer W by first elevating wafer W and then spraying purge gas 128 so that the pressure above and below wafer W remains substantially the same during the purge process.

Where purge gas 128 is sprayed on wafer W while wafer W rests on susceptor 118, wafer W may slide around on susceptor 118 due to a strong spraying force of purge gas 128. Therefore, in order to prevent such a wafer sliding problem, purge gas 128 is preferably sprayed on wafer W while wafer W is separated from susceptor 118 by distance D. Where purge gas 128 is sprayed while wafer W is separated from susceptor 118 by distance D, purge gas 128 is diffused into the space between wafer W and susceptor 118 and also into a region above wafer W, causing the pressure above and below wafer W to be substantially the same and preventing wafer W from moving. Wafer W is therefore prevented from sliding around. After purging is completed, wafer W is removed from process chamber 100 through slit door valve 122 in a step S212. Thereafter other processes such as metallization may be performed on wafer W to complete the formation of the semiconductor device.

According to selected embodiments of the invention, a process recipe used to perform pumping and purging steps within a process chamber may be modified to prevent a wafer from sliding. In addition, a wafer loading and unloading method may be performed without guide pins, which may cause wafer or process defects.

Although the above description relates to wafer loading and unloading procedures performed in a plasma reinforced CVD device used for a PETEOS film deposition process, these procedures are merely teaching examples. Embodiments of the invention may be applied to many different kinds of semiconductor manufacturing apparatuses employing pumping or purging steps.

As described above, according to some embodiments of the invention, pumping and purge operations for the interior of a process chamber are performed while a wafer is elevated above a susceptor using lift pins. As a result, upper and lower regions of the wafer are maintained at the same or similar pressure, effectively preventing the wafer from sliding without requiring additional stabilizing equipment.

The foregoing exemplary embodiments are teaching examples. Those of ordinary skill in the art will understand that various changes in form and details may be made to the exemplary embodiments without departing from the scope of the invention as defined by the claims.

What is claimed:

1. A method, comprising:
introducing a semiconductor wafer into a process chamber in a semiconductor manufacturing apparatus;
mounting the wafer on an elevated lift pin in the process chamber;
with the wafer mounted on the elevated lift pin, pumping air from the process chamber;
after pumping the air from the process chamber, lowering the lift pin to mount the wafer on a susceptor;
with the wafer mounted on the susceptor, performing a process on the wafer.

2. The method of claim 1, further comprising:
after performing the process on the wafer, elevating the lift pin to separate the wafer from the susceptor;
with the wafer separated from the susceptor, injecting a purge gas into the process chamber; and
after injecting the purge gas into the process chamber, removing the wafer from the process chamber.

3. The method of claim 2, wherein the air is pumped from the process chamber using a turbo pump.

4. The method of claim 3, wherein the wafer is introduced into and removed from the process chamber through a slit door valve.

5. The method of claim 2, wherein the process performed on the wafer comprises a plasma-enhanced tetraethylorthosilicate (PETEOS) film deposition process.

6. The method of claim 2, wherein the wafer is separated from the susceptor by a distance “C” while the air is pumped from the process chamber, and the wafer is separated from the susceptor by a distance “D” while the purge gas is injected into the process chamber.

7. The method of claim 5, wherein the process is performed using a process gas comprising oxygen O₂ and tetra-ethyl-ortho-silicate (TEOS).

8. The method of claim 3, further comprising:
by operation of the turbo pump, maintaining the process chamber at an interior pressure of about 10⁻⁶ torr while performing the process on the wafer.

9. The method of claim 2, wherein the wafer is introduced in the process chamber from a transfer chamber, wherein an interior pressure of the transfer chamber is maintained at about 10⁻³ torr by a dry pump.

10. A method of loading and unloading a wafer in a semiconductor manufacturing apparatus, the method comprising:
introducing the wafer into a process chamber;
mounting the wafer on an elevated lift pin such that the wafer is separated from a susceptor by a distance “C”;
with the wafer mounted on the elevated lift pin and separated from the susceptor by the distance “C”, performing a pumping operation to control an internal pressure of the process chamber;
lowering the lift pin to load the wafer onto the susceptor;
with the wafer loaded on the susceptor, performing a process on the wafer;
after performing the process on the wafer, elevating the lift pin to separate the wafer from the susceptor by a distance “D”;
with the wafer separated from the susceptor by the distance “D”, injecting a purge gas into the process chamber to create a constant pressure in the process chamber above and below the wafer; and
after injecting the purge gas into the process chamber, removing the wafer from the process chamber.

11. The method of claim 10, wherein the air is pumped from the process chamber using a turbo pump.

12. The method of claim 11, wherein the wafer is introduced into and removed from the process chamber through a slit door valve.

13. The method of claim 10, wherein the process performed on the wafer comprises a plasma-enhanced tetraethylorthosilicate (PETEOS) film deposition process.

14. The method of claim 13, wherein the process is performed using a process gas comprising oxygen O₂ and tetra-ethyl-ortho-silicate (TEOS).

15. The method of claim 11, further comprising:
by operation of the turbo pump, maintaining the process chamber at an interior pressure of about 10⁻⁶ torr while performing the process on the wafer.

16. The method of claim 10, wherein the wafer is introduced in the process chamber from a transfer chamber, wherein an interior pressure of the transfer chamber is maintained at about 10⁻³ torr by a dry pump.

17. A method of unloading a wafer in a semiconductor device manufacturing apparatus, the method comprising:
mounting the wafer on a susceptor within a process chamber and performing a process on the wafer;
after performing the process on the wafer, elevating a lift pin to separate the wafer from the susceptor;
with the wafer separated from the susceptor, injecting a purge gas into the process chamber; and
after injecting the purge gas into the process chamber, removing the wafer from the process chamber.

18. The method of claim 17, further comprising;
while performing the process on the wafer, controlling an internal pressure of the process chamber by operation of a turbo pump.

19. The method of claim 18, wherein the wafer is removed from the process chamber through a slit door valve.

20. The method of claim 17, wherein the process performed on the wafer comprises a plasma-enhanced tetraethylorthosilicate (PETEOS) film deposition process.

21. The method of claim 20, wherein the process is performed using a process gas comprising oxygen O₂ and tetra-ethyl-ortho-silicate (TEOS).
